(19) United States
(12) Patent Application Publication
(10) Pub. No.: US 2023/0171944 A1
(43) Pub. Date: Jun. 1, 2023

(54) A Memory Device Comprising an Electrically Floating Body Transistor

(71) Applicant: Zeno Semiconductor, Inc., Sunnyvale, CA (US)

(72) Inventors: Asen Asenov, Glasgow (GB); Valerii Nebesnyi, Kouklia (CY); Yuniarto Widjaja, Cupertino, CA (US); Jin-Woo Han, San Jose, CA (US); Tapas Dutta, Glasgow (GB); Fikru Adamu-Lema, Glasgow (GB)

(21) Appl. No.: 17/927,620

(22) PCT Filed: May 25, 2021
(86) PCT No.: PCT/US2021/033984

§ 371 Date: Nov. 23, 2022

Related U.S. Application Data
(60) Provisional application No. 63/031,069, filed on May 28, 2020.

(51) Int. Cl. H10B 12/00

(52) U.S. Cl. CPC H10B 12/20

(57) ABSTRACT

A semiconductor memory cell includes a floating body region configured to be charged to a level indicative of a state of the memory cell. A first region is in electrical contact with the floating body region. A second region is in electrical contact with the floating body region and is spaced apart from the first region. A gate is positioned between the first and second regions. A buried layer is provided beneath the floating body region. An insulating layer is configured to insulate the memory cell from adjacent memory cells in a first direction. A buried insulating layer is configured to insulate the memory cell from adjacent memory cells in a second direction perpendicular to the first direction.

### FIELD OF THE INVENTION

The present invention relates to semiconductor memory technology. More specifically, the present invention relates to a semiconductor memory device comprising an electrically floating body transistor.

### BACKGROUND OF THE INVENTION

Semiconductor memory devices are used extensively to store data. Memory devices can be characterized according to two general types: volatile and non-volatile. Volatile memory devices such as static random access memory (SRAM) and dynamic random access memory (DRAM) lose data that is stored therein when power is not continuously supplied thereto.

A DRAM cell without a capacitor has been investigated previously. Such memory eliminates the capacitor used in the conventional 1T/1C memory cell, and thus is easier to scale to smaller feature size. In addition, such memory allows for a smaller cell size compared to the conventional 1T/1C memory cell. Chatterjee et al. have proposed a Taper Isolated DRAM cell concept in “Taper Isolated Dynamic Gain RAM Cell”, P. K. Chatterjee et al., pp. 698-699, International Electron Devices Meeting, 1978 (“Chatterjee-1”), “Circuit Optimization of the Taper Isolated Dynamic Gain RAM Cell for VLSI Memories”, P. K. Chatterjee et al., pp. 22-23, IEEE International Solid-State Circuits Conference, February 1979 (“Chatterjee-2”), and “dRAM Design Using the Taper-Isolated Dynamic RAM Cell”, J. E. Leiss et al., pp. 337-344, IEEE Journal of Solid-State Circuits, vol. SC-17, no. 2, April 1982 (“Leiss”), all of which are hereby incorporated herein, in their entireties, by reference thereto. The holes are stored in a local potential minimum, which looks like a bowling alley, where a potential barrier for stored holes is provided. The channel region of the Taper Isolated DRAM cell contains a deep n-type implant and a shallow p-type implant. As shown in “A Survey of High-Density Dynamic RAM Cell Concepts”, P. K. Chatterjee et al., pp. 827-839, IEEE Transactions on Electron Devices, vol. ED-26, no. 6, June 1979 (“Chatterjee-3”), which is hereby incorporated herein, in its entirety, by reference thereto, the deep n-type implant isolates the shallow p-type implant and connects the n-type source and drain regions.

Terada et al. have proposed a Capacitance Coupling (CC) cell in “A New VLSI Memory Cell Using Capacitance Coupling (CC) Cell”, K. Terada et al., pp. 1319-1324, IEEE Transactions on Electron Devices, vol. ED-31, no. 9, September 1984 (“Terada”), while Erb has proposed Stratified Charge Memory in “Stratified Charge Memory”, D. M. Erb, pp. 24-25, IEEE International Solid-State Circuits Conference, February 1978 (“Erb”), both of which are hereby incorporated herein, in their entireties, by reference thereto.

DRAM based on the electrically floating body effect has been proposed both in silicon-on-insulator (SOI) substrate (see for example “The Multistable Charge-Controlled Memory Effect in SOI Transistors at Low Temperatures”, Tack et al., pp. 1373-1382, IEEE Transactions on Electron Devices, vol. 37, May 1990 (“Tack”), “A Capacitor-less 1T-DRAM Cell”, S. Okhonin et al., pp. 85-87, IEEE Electron Device Letters, vol. 23, no. 2, February 2002 and “Memory Design Using One-Transistor Gain Cell on SOI”, T. Ohsawa et al., pp. 152-153, Tech. Digest, 2002 IEEE International Solid-State Circuits Conference, February 2002, all of which are hereby incorporated herein, in their entireties, by reference thereto) and in bulk silicon (see for example “A one transistor cell on bulk substrate (1T-Bulk) for low-cost and high density eDRAM”, R. Ranica et al., pp. 128-129, Digest of Technical Papers, 2004 Symposium on VLSI Technology, June 2004 (“Ranica-1”), “Scaled 1T-Bulk Devices Built with CMOS 90 nm Technology for Low-Cost eDRAM Applications”, R. Ranica et al., 2005 Symposium on VLSI Technology, Digest of Technical Papers (“Ranica-2”), “Further Insight Into the Physics and Modeling of Floating-Body Capacitorless DRAMs”, A. Villaret et al, pp. 2447-2454, IEEE Transactions on Electron Devices, vol. 52, no. 11, November 2005 (“Villaret”), “Simulation of intrinsic bipolar transistor mechanisms for future capacitor-less eDRAM on bulk substrate”, R. Pulicani et al., pp. 966-969, 2010 17th IEEE International Conference on Electronics, Circuits, and Systems (ICECS) (“Pulicani”), all of which are hereby incorporated herein, in their entireties, by reference thereto).

Widjaja and Or-Bach describes a bi-stable SRAM cell incorporating a floating body transistor, where more than one stable state exists for each memory cell (for example as described in U.S. Pat. No. 8,130,548 to Widjaj a et al., titled “Semiconductor Memory Having Floating Body Transistor and Method of Operating” (“Widjaja-1”), U.S. Pat. No. 8,077,536, “Method of Operating Semiconductor Memory Device with Floating Body Transistor Using Silicon Controlled Rectifier Principle” (“Widjaja-2”), U.S. Pat. No. 9,230,651, “Memory Device Having Electrically Floating Body Transistor” (“Widjaja-3”), all of which are hereby incorporated herein, in their entireties, by reference thereto). The bi-stability is achieved due to the applied back bias which causes impact ionization and generates holes to compensate for the charge leakage current and recombination.

### SUMMARY OF THE INVENTION

According to an aspect of the present invention, a semiconductor memory cell includes: a floating body region configured to be charged to a level indicative of a state of the memory cell; a first region in electrical contact with the floating body region; a second region in electrical contact with said floating body region and spaced apart from the first region; a gate positioned between the first and second regions; a buried layer beneath the floating body region; an insulating layer configured to insulate the memory cell from adjacent memory cells in a first direction; and a buried insulating layer configured to insulate the memory cell from adjacent memory cells in a second direction perpendicular to the first direction.

In at least one embodiment, the buried insulating layer does not extend to a surface of the memory cell, but is buried beneath the first and second regions.

In at least one embodiment, the buried layer is configured to inject charge into or extract charge out of the floating body region to maintain the state of the memory cell.

In at least one embodiment, the first region has a first conductivity type selected from a p-type conductivity type and an n-type conductivity type; the floating body region has a second conductivity type selected from the p-type and n-type conductivity types, the second conductivity type being different from the first conductivity type; the second region has the first conductivity type; and the buried layer has the first conductivity type.

In at least one embodiment, the semiconductor memory further includes a substrate beneath the buried layer, the substrate having a first conductivity type selected from a p-type conductivity type and an n-type conductivity type; wherein the first region has a second conductivity type selected from the p-type and n-type conductivity types, the second conductivity type being different from the first conductivity type; wherein the floating body region has the first conductivity type; wherein the second region has the second conductivity type; and wherein the buried layer has the second conductivity type and is positioned between the floating body region and the substrate.

In at least one embodiment, a bottom of the buried insulating layer ends inside the buried layer; and a bottom of the insulating layer ends inside the buried layer.

In at least one embodiment, a bottom of the buried insulating layer extends below a bottom of the buried layer; and a bottom of the insulating layer ends inside the buried layer.

In at least one embodiment, a semiconductor memory array comprises a plurality of any of the semiconductor memory cells described above.

According to an aspect of the present invention, a semiconductor memory cell includes: a bi-stable floating body transistor and an access transistor connected in series; the bistable floating body transistor comprising a first floating body region and a first region in electrical contact with the first floating body region; the access transistor comprising a second body region and a second region in contact with the second body region; a third region in contact with the first floating body region and the second body region; a gate positioned between the first region and the third region; a buried layer beneath the first floating body region; an insulating layer configured to insulate the memory cell from adjacent memory cells in a first direction; and a buried insulating layer configured to insulate the first floating body region from an adjacent memory cell in a second direction perpendicular to the first direction, and to insulate the first floating body region from the second body region.

In at least one embodiment, the buried insulating layer is additionally provided beneath the second region to insulate the second body region on a side opposite of a side where the buried insulating layer insulates the second body region from the first floating body region.

In at least one embodiment, the buried layer is also provided beneath the second body region.

In at least one embodiment, the buried insulating layer does not extend to a surface of the memory cell.

In at least one embodiment, the buried layer is configured to inject charge into or extract charge out of the first floating body region to maintain the state of the memory cell.

In at least one embodiment, the semiconductor memory cell further includes a substrate beneath the buried layer.

In at least one embodiment, a bottom of the buried insulating layer ends inside the buried layer; and a bottom of the insulating layer ends inside the buried layer.

In at least one embodiment, a bottom of the buried insulating layer extends below a bottom of the buried layer; and a bottom of the insulating layer ends inside the buried layer.

In at least one embodiment, a semiconductor memory array includes a plurality of the semiconductor memory cells of any of the type described above.

According to an aspect of the present invention, a method of making a semiconductor memory cell includes: performing oxygen ion implantation and thermal annealing to form buried insulating layers; forming a fin; forming a buried layer region; forming an insulating layer by silicon oxide deposition, followed by planarization and etch back; and forming gate dielectric, gate, and source and drain regions.

According to an aspect of the present invention, a method of making a semiconductor memory cell includes: he method comprising: forming a buried layer in a substrate by ion implantation, epitaxial growth or through a solid state diffusion process; forming a fin; forming insulating layers; performing oxygen ion implantation and thermal annealing to form the buried insulating layers; forming gate dielectric and a gate; and forming source and drain regions.

According to an aspect of the present invention, a method of making semiconductor memory cells includes: forming a buried layer in a substrate by an ion implantation process or epitaxial growth or through a solid state diffusion process; forming a fin region by masking a region of the substrate and etching regions adjacent to the region that was masked; filling regions between adjacent fin regions with a sacrificial layer; masking regions where buried insulating layers are not to be formed; forming a spacer mask to protect the fin; etching of the sacrificial layer to expose a bottom portion of the fin; and performing thermal oxidation and annealing until the bottom portion of the fin is consumed into the buried insulating layer.

According to an aspect of the present invention, a method of making semiconductor memory cells includes: masking regions of a substrate where buried insulating layers are not to be formed; etching the substrate; filling voids formed by the etching with silicon oxide fill to form the buried insulating layers; and removing the masking.

In at least one embodiment, the method further includes: masking a portion of the substrate where a fin is to be formed; etching the substrate at unmasked locations adjacent the masked portion; filling in the etched out regions on both sides of the fin with silicon oxide; removing the masking; and epitaxially, laterally overgrowing silicon to grow the fin.

According to an aspect of the present invention, a method of making buried insulator layer in a semiconductor memory cell includes: epitaxially growing SiGe and Si regions respectively on a substrate; etching the SiGe and Si regions where the buried insulator layer is to be formed; epitaxially growing silicon; planarizing the epitaxially grown silicon; forming a fin; etching the SiGe regions; and forming the buried insulator layer.

These and other advantages and features of the invention will become apparent to those persons skilled in the art upon reading the details of the products and methods as more fully described below.

### BRIEF DESCRIPTION OF THE DRAWINGS

In the course of the detailed description to follow, reference will be made to the attached drawings. These drawings show different aspects of the present invention an, where appropriate, reference numerals illustrating like structures, components, materials and/or elements in different figures are labeled similarly. It is understood that various combinations of the structures, components, materials and/or elements, other than those specifically shown, are contemplated and are within the scope of the present invention.

FIGS. 1, 2, and 3A illustrate cross-sectional views of memory cells described in prior art.

FIGS. 3B and 3C illustrate layout views of the prior art memory cell shown in FIG. 3A.

FIGS. 4A and 4B schematically illustrate cross-sectional views of a memory cell according to an embodiment of the present invention.

FIGS. 5A-5C are schematic, layout views of a memory array formed by memory cells shown in FIGS. 4A and 4B.

FIG. 6 is a schematic, cross-sectional illustration of a plurality of memory cells along the I-I′ direction shown in FIGS. 5A-5C.

FIG. 7A is an equivalent circuit representation of a memory array formed by memory cells shown in FIGS. 4A and 4B.

FIGS. 7B-7D illustrate exemplary bias conditions applied to the memory array shown in FIG. 7A to perform read and write operations to a memory cell according to an embodiment of the present invention.

FIGS. 8A-8B are schematic, layout views of a memory array according to another embodiment of the present invention, formed by memory cells shown in FIGS. 4A and 4B.

FIG. 9 is a schematic, cross-sectional illustration of a plurality of memory cells along the I-I′ direction shown in FIGS. 8A-8B.

FIG. 10 is an equivalent circuit representation of the memory array illustrated in FIGS. 8A-8B.

FIGS. 11A, 11B, and 12 schematically illustrate cross-sectional views of a memory cell having a floating body transistor and an access transistor according to another embodiment of the present invention.

FIG. 13 is a schematic, cross-sectional illustration of a plurality of memory cells shown in FIG. 11A.

FIG. 14 is a schematic, cross-sectional illustration of a plurality of memory cells shown in FIG. 12.

FIG. 15 is an equivalent circuit representation of a memory array formed by memory cells shown in FIGS. 11A, 11B, and 12.

FIG. 16 is an equivalent circuit representation of a memory array according to another embodiment of the present invention, formed by memory cells shown in FIGS. 11A, 11B, and 12.

FIGS. 17A-17E illustrate fabrication steps of memory cells according to an embodiment of the present invention.

FIGS. 18A-18E illustrate fabrication steps of memory cells according to another embodiment of the present invention.

FIGS. 19A-19F illustrate fabrication steps of memory cells according to another embodiment of the present invention.

FIGS. 20A-20F illustrate fabrication steps of memory cells according to another embodiment of the present invention.

FIGS. 21A-21F illustrate fabrication steps of memory cells according to another embodiment of the present invention.

### DETAILED DESCRIPTION OF THE INVENTION

Before the present memory cells, arrays and methods are described, it is to be understood that this invention is not limited to particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, the preferred methods and materials are now described. All publications mentioned herein are incorporated herein by reference to disclose and describe the methods and/or materials in connection with which the publications are cited.

It must be noted that as used herein and in the appended claims, the singular forms “a”, “an”, and “the” include plural referents unless the context clearly dictates otherwise. Thus, for example, reference to “a cell” includes a plurality of such cells and reference to “the region” includes reference to one or more regions and equivalents thereof known to those skilled in the art, and so forth.

The publications discussed herein are provided solely for their disclosure prior to the filing date of the present application. The dates of publication provided may be different from the actual publication dates which may need to be independently confirmed.

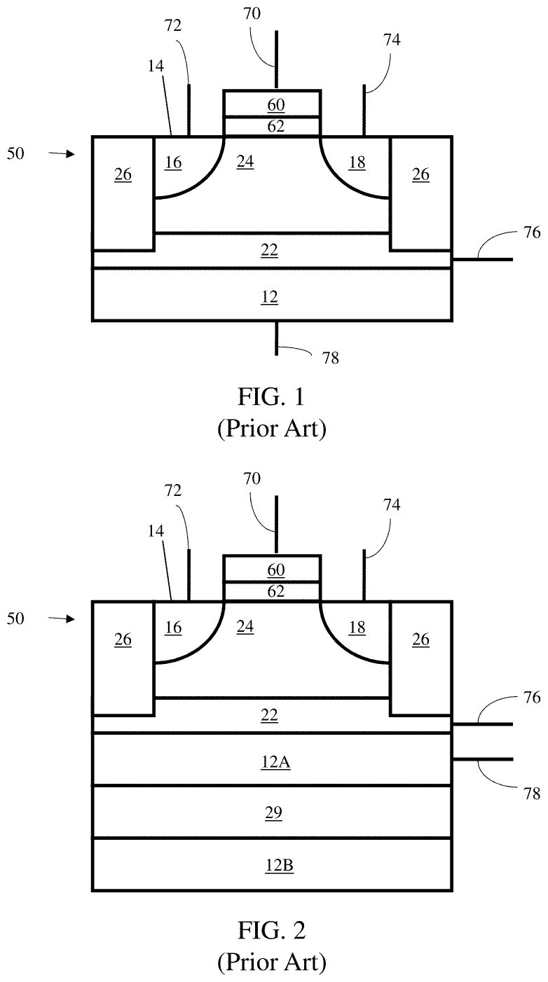

FIG. 1 illustrates a bi-stable SRAM memory cell 50, for example, as described in Widjaja-1, Widjaja-2, and Widjaja-3. Memory cell 50 includes a substrate 12 of a first conductivity type such as p-type, for example. Substrate 12 is typically made of silicon, but may also comprise, for example, germanium, silicon germanium, gallium arsenide, carbon nanotubes, and/or other semiconductor materials. In some embodiments of the invention, substrate 12 can be the bulk material of the semiconductor wafer. In another embodiment shown in FIG. 2, substrate 12A of a first conductivity type (for example, p-type) can be a well of the first conductivity type embedded in a well 29 of the second conductivity type, such as n-type. The well 29 in turn can be another well inside substrate 12B of the first conductivity type (for example, p-type). In another embodiment, well 12A can be embedded inside the bulk of the semiconductor wafer of the second conductivity type (for example, n-type). These arrangements allow for segmentation of the substrate terminal 78, which is connected to region 12A. To simplify the description, the substrate 12 will usually be drawn as the semiconductor bulk material as it is in FIG. 1.

Memory cell 50 also includes a buried layer region 22 of a second conductivity type, such as n-type, for example; a floating body region 24 of the first conductivity type, such as p-type, for example; and source/drain regions 16 and 18 of the second conductivity type, such as n-type, for example.

Buried layer 22 may be formed by an ion implantation process on the material of substrate 12. Alternatively, buried layer 22 can be grown epitaxially on top of substrate 12 or formed through a solid state diffusion process.

The floating body region 24 of the first conductivity type is bounded on top by source line region 16, drain region 18, and insulating layer 62 (or by surface 14 in general), on the sides by insulating layer 26, and on the bottom by buried layer 22. Floating body 24 may be the portion of the original substrate 12 above buried layer 22 if buried layer 22 is implanted. Alternatively, floating body 24 may be epitaxially grown. Depending on how buried layer 22 and floating body 24 are formed, floating body 24 may have the same doping as substrate 12 in some embodiments or a different doping, if desired in other embodiments.

A source line region 16 having a second conductivity type, such as n-type, for example, is provided in floating body region 24, so as to bound a portion of the top of the floating body region in a manner discussed above, and is exposed at surface 14. Source line region 16 may be formed by an implantation process on the material making up substrate 12, according to any implantation process known and typically used in the art. Alternatively, a solid state diffusion or a selective epitaxial growth process could be used to form source line region 16.

A bit line region 18, also referred to as drain region 18, having a second conductivity type, such as n-type, for example, is also provided in floating body region 24, so as to bound a portion of the top of the floating body region in a manner discussed above, and is exposed at cell surface 14. Bit line region 18 may be formed by an implantation process on the material making up substrate 12, according to any implantation process known and typically used in the art. Alternatively, a solid state diffusion or a selective epitaxial growth process could be used to form bit line region 18.

A gate 60 is positioned in between the source line region 16 and the drain region 18, above the floating body region 24. The gate 60 is insulated from the floating body region 24 by an insulating layer 62. Insulating layer 62 may be made of silicon oxide and/or other dielectric materials, including high-K dielectric materials, such as, but not limited to, tantalum peroxide, titanium oxide, zirconium oxide, hafnium oxide, and/or aluminum oxide. The gate 60 may be made of, for example, polysilicon material or metal gate electrode, such as tungsten, tantalum, titanium and their nitrides.

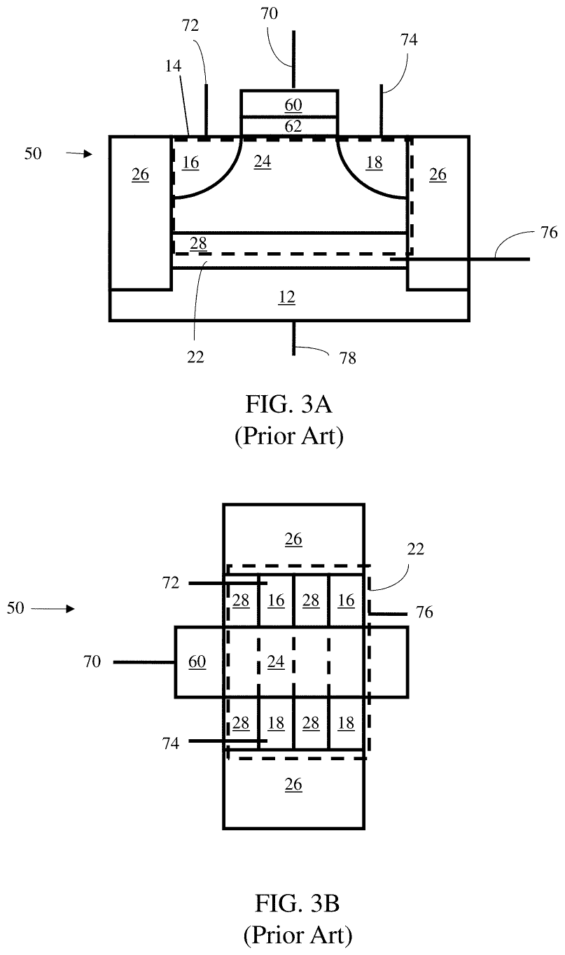

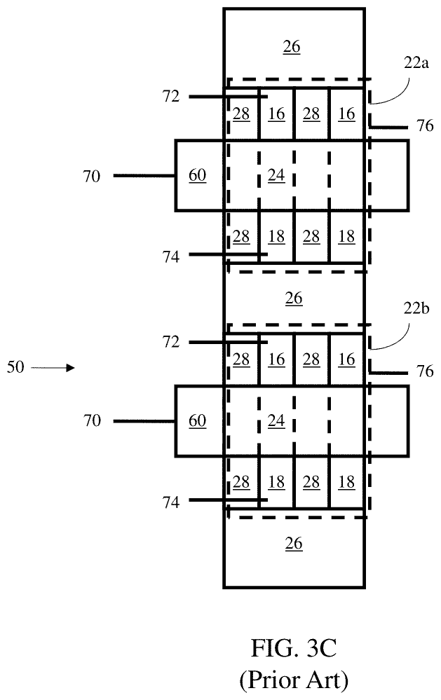

Insulating layers 26 (like, for example, shallow trench isolation (STI)), may be made of silicon oxide, for example, though other insulating materials may be used. Insulating layers 26 insulate memory cell 50 from adjacent memory cells 50. The bottom of insulating layer 26 may reside inside the buried region 22 allowing buried region 22 to be continuous as shown in FIGS. 1 and 2. Alternatively, the bottom of insulating layer 26 may reside below the buried region 22 as in FIG. 3A. This requires a shallower insulating layer 28, which insulates the floating body region 24, but allows the buried layer 22 to be continuous in one direction, for example the perpendicular direction of the cross-sectional view shown in FIG. 3A as shown in the schematic layout view shown in FIG. 3B. As a result, different bias conditions may be applied to different buried layer regions 22 isolated by the insulating layer 26. FIG. 3C illustrates two buried layer regions 22a and 22b isolated by insulating layer 26, which can be connected to different terminals and biased independently. For simplicity, only memory cell 50 with continuous buried region 22 in all directions will be shown from hereon.

Cell 50 includes several terminals: word line (WL) terminal 70 electrically connected to gate 60, bit line (BL) terminal 74 electrically connected to bit line region 18, source line (SL) terminal 72 electrically connected to source line region 16, buried well (BW) terminal 76 electrically connected to buried layer 22, and substrate terminal 78 electrically connected to the substrate 12. Alternatively, the SL terminal 72 may be electrically connected to region 18 and BL terminal 74 may be electrically connected to region 16.

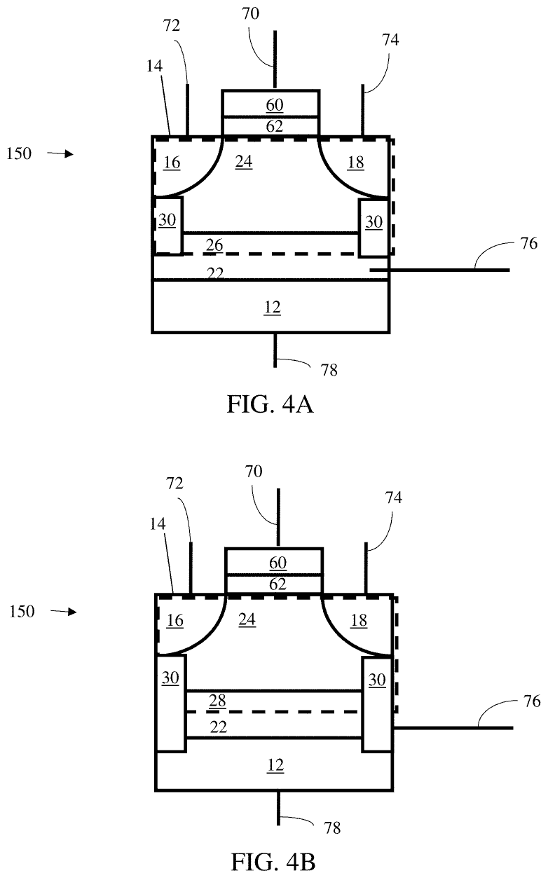

FIG. 4A illustrates a cross-sectional view of memory cell 150 according to an embodiment of the present invention. Memory cell 150 includes a floating body region 24, which is bounded from adjacent memory cells 150 by an insulating layer 26 (like, for example, shallow trench isolation (STI)) in one direction (for example the perpendicular direction of the cross-sectional view shown in FIG. 4A), and by a buried insulating layer 30 in the other direction (for example the direction of the cross-sectional view plane shown in FIG. 4A). Unlike the insulating layers 26 of the prior art cells 50 of FIGS. 1-3C, buried insulating layer 30 does not extend to the cell surface 14. Rather, insulating layers 30 are buried beneath the regions 16 and 18, respectively, thereby allowing the cells 150 to be arranged in a more compact configuration than is achievable with the cells 50. The bottom of the buried insulating layer 30 and the bottom of the insulating layer 26 may be aligned inside the buried layer 22. Alternatively, the bottom of buried insulating layer 30 and the bottom of insulating layer 28 may not be aligned as shown in FIG. 4B. For example, as shown in FIG. 4B, the bottom of buried insulating layer 30 may reside below the buried region 22. This requires a shallower insulating layer 28, which insulates the floating body region 24, but allows the buried layer 22 to be continuous in one direction, for example the perpendicular direction of the cross-sectional view shown in FIG. 4B.

Buried insulating layer 30 may be formed using oxygen implantation, for example the local separation by implantation of oxygen (SIMOX) process as described in He et al., “Experimental results on drain and source on insulator MOSFETs fabricated by local SIMOX technology”, Solid-State Electronics 47, pp. 1061-1067, 2003, Koonath et al., “Sculpting of three-dimensional nano-optical structure in silicon”, Applied Physics Letter, vol. 83, no. 24, pp. 4909-4911, 2003, and Lv et al., “Fabrication of Self-aligned Drain and Source on Insulator MOSFET with Dielectric Pocket by Local SIMOX Technology”, IEEE International SOI Conference, pp. 99-100, 2005, all of which are hereby incorporated herein, in their entireties, by reference thereto; SiGe epitaxy followed by selective SiGe removal and dielectric fill, for example the Silicon-on-Nothing (SON) process as described in Jurczak et al., “Silicon-on-Nothing (SON)— an Innovative Process for Advanced CMOS”, IEEE Transactions on Electron Devices, vol. 47, no. 11, pp. 2179-2187, November 2000, Oh et al., “A 4-Bit Double SONOS Memory (DSM) with 4 Storage Nodes per Cell for Ultimate Multi-Bit Operation”, Symposium on VLSI Technology, 2006, Kim et al., “Silicon on Replacement Insulator (SRI) Floating Body Cell (FBC) Memory”, Symposium on VLSI Technology, pp. 165-166, 2010, and U.S. Pat. No. 8,264,875, “Semiconductor Memory Device Having an Electrically Floating Body Transistor”, all of which are hereby incorporated herein, in their entireties, by reference thereto; SiGe and Si epitaxial growth and selective SiGe removal, for example the Partially Insulated Field-Effect Transistor (PiFET) as described in Yeo et al., “A Partially Insulated Field-Effect Transistor (PiFET) as a Candidate for Scaled Transistors, IEEE Electron Device Letters, vol, 25, no. 6, pp. 387-389, June 2004, which is hereby incorporated herein, in its entirety, by reference thereto; localized selective silicon oxidation, for example, as described in Song, Yi, et al. “Performance breakthrough in gate-all-around nanowire n- and p-type MOSFETs fabricated on bulk silicon substrate.” IEEE transactions on electron devices 59.7 (2012): 1885-1890; Tian, Yu, et al. “New self-aligned silicon nanowire transistors on bulk substrate fabricated by epi-free compatible CMOS technology: Process integration, experimental characterization of carrier transport and low frequency noise.” 2007 IEEE International Electron Devices Meeting. IEEE, 2007, all of which are hereby incorporated herein, in their entireties, by reference thereto; confined epitaxial lateral overgrowth over oxide, for example, as described in Czornomaz, L., et al. “Confined epitaxial lateral overgrowth (CELO): A novel concept for scalable integration of CMOS-compatible InGaAs-on-insulator MOSFETs on large-area Si substrates.” 2015 Symposium on VLSI Technology (VLSI Technology). IEEE, 2015; Convertino, Clarissa, et al. “InGaAs FinFETs directly integrated on silicon by selective growth in oxide cavities.” Materials 12.1 (2019): 87, all of which are hereby incorporated herein, in their entireties, by reference thereto.

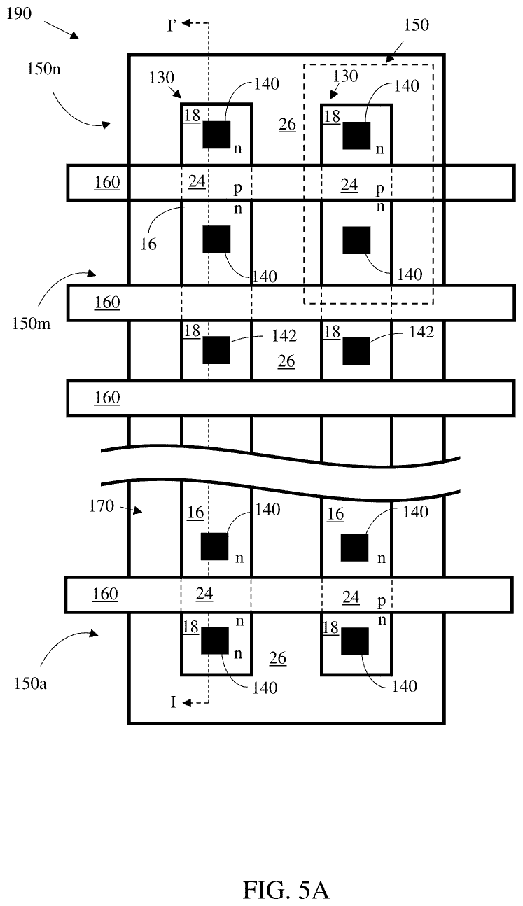

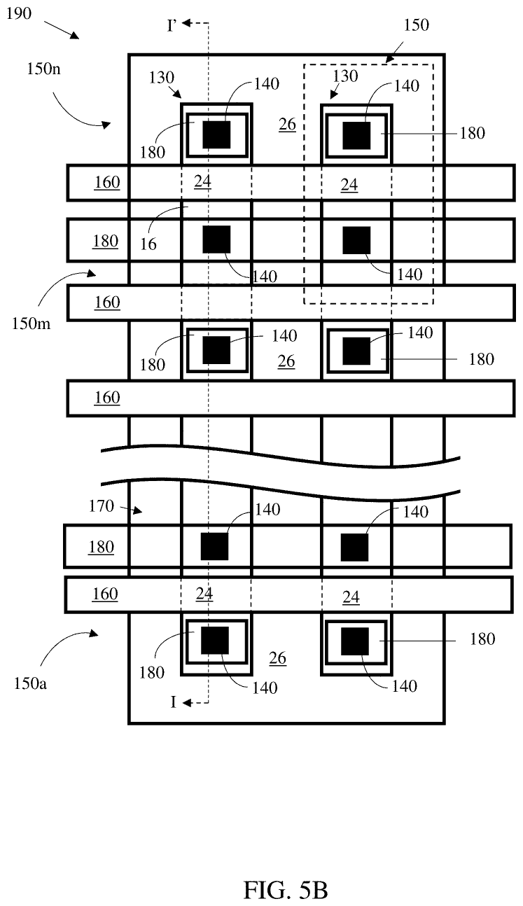

FIG. 5A illustrates a layout view of memory array 190 comprising a plurality of rows and columns of memory cells 150. The memory cell 150 is formed by the DIFF or FIN 130, POLY 160, and BNWL layers 170. Also shown in FIG. 5A is CONT 140, which connects to the conductive element defined by MTL1 layer (shown in FIG. 5B), forming connection between the source line region 16, bit line region 18 to the SL terminal 72 and BL terminal 74, respectively. Layers DIFF or FIN 130, POLY 160, BNWL 170, CONT 140, and MTL1 are exemplary mask layers used in photolithography steps to form patterns during semiconductor fabrication process. For simplicity, the connection between the gate region 60 and WL terminal 70, buried layer 22 and BW terminal 76, and substrate 12 and the substrate terminal 78 are not illustrated in FIG. 5B.

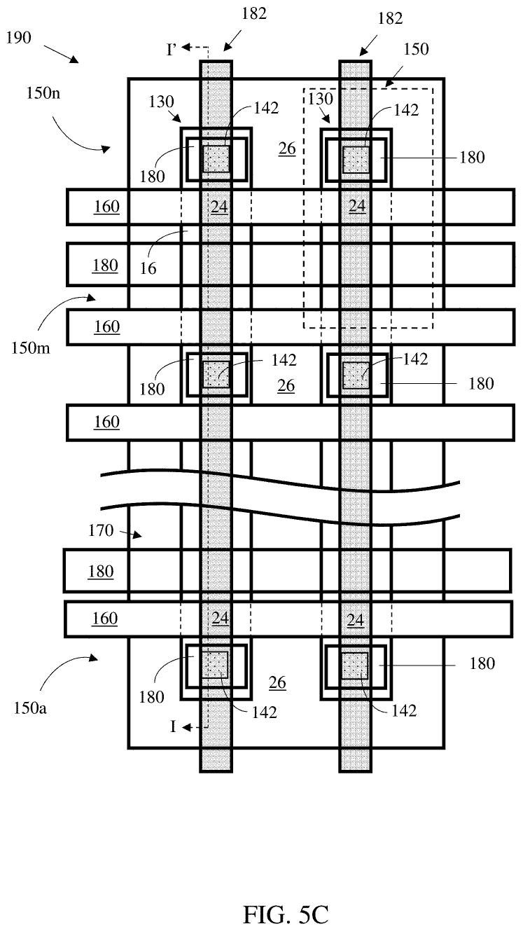

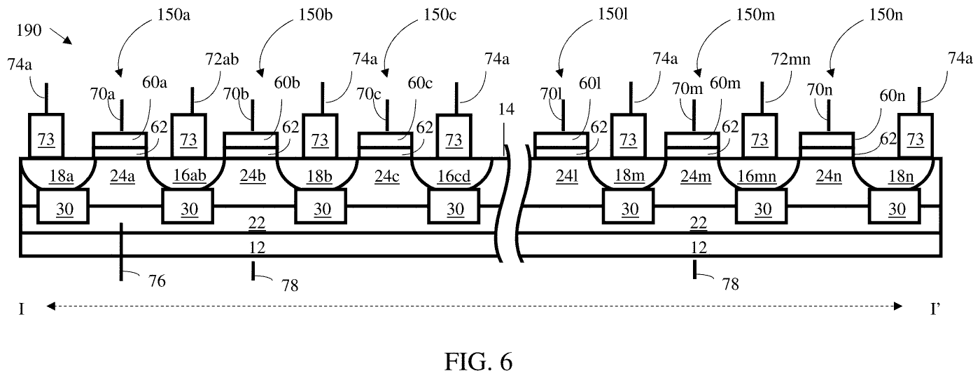

The DIFF or FIN layer 130 defines the active regions of the memory cell 150, which comprise the floating body region 24, source line region 16, and bit line region 18. The insulating layer 26 is defined by the space between the DIFF or FIN layer 130. The gate region 60 is defined by the POLY layer 160. The BNWL layer 170 defines the region where the buried layer region 22 is formed. CONT layer 140 defines the conductive element 73 (e.g., see FIG. 6), which connects the source line region 16 to the SL terminal 72 and the bit line region 18 to the BL terminal 74 through a conductive element defined by MTL1 layer 180 (which subsequently may be connected to other conductive elements, for example defined by MTL2 layer 182 through VIA1 layer 142 as shown in FIG. 5C). The buried insulating layers 30 are formed in the regions between adjacent POLY layers 160 in FIGS. 5A-5C and can be seen in the cross-sectional illustration in FIG. 6. VIA1 and MTL2 layers are other exemplary mask layers used to form the memory arrays 190.

FIG. 6 illustrates a cross-sectional view of memory array 190 showing a plurality of “n” memory cells 150 along the I-I′ direction shown in FIGS. 5A-5C, where “n” is a positive integer, which may range between 8 and 128. However, this embodiment is not limited to the stated range, as fewer than eight or more than one hundred and twenty eight may be formed.

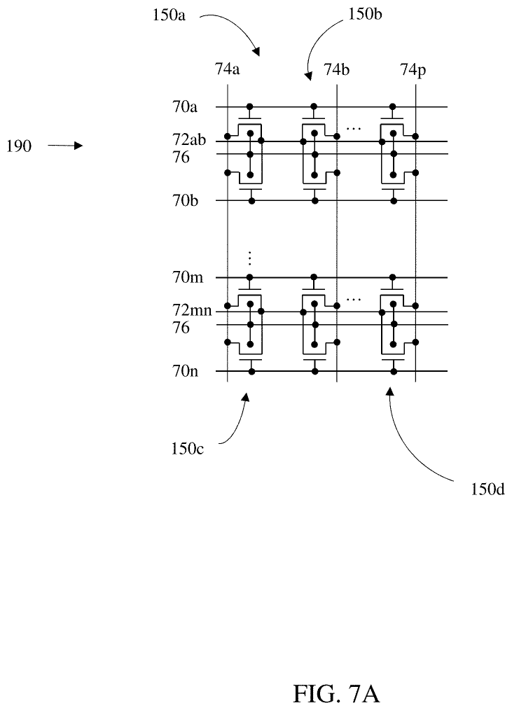

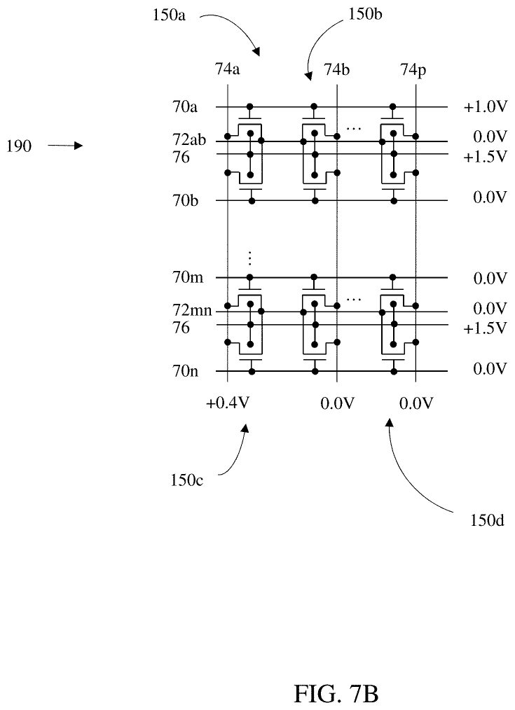

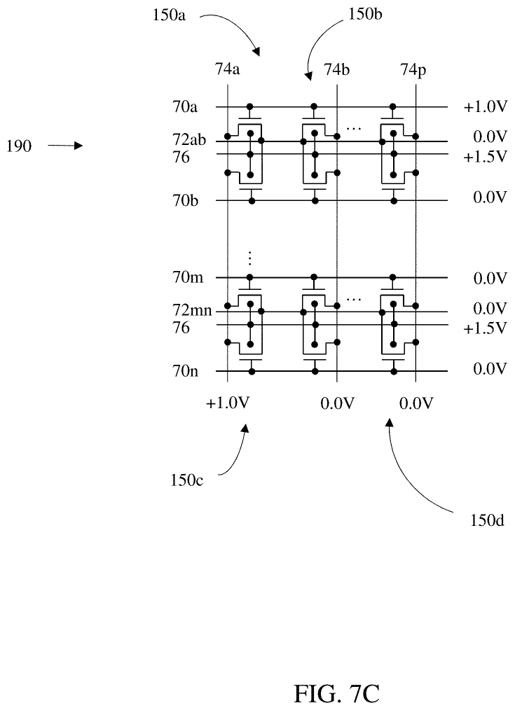

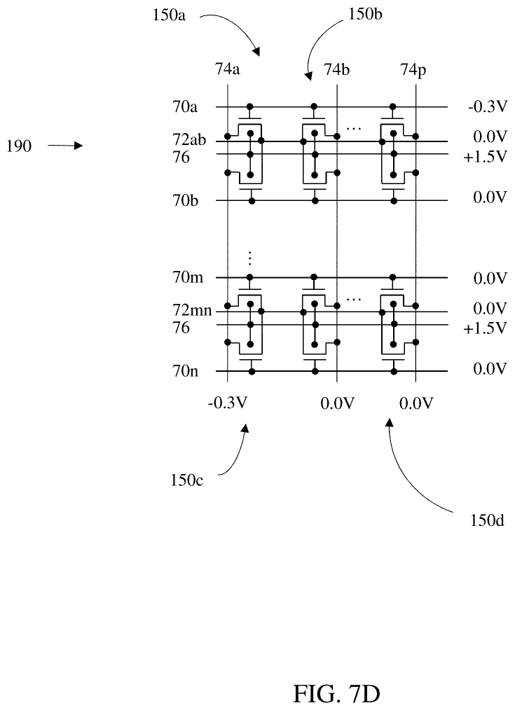

FIG. 7A shows an equivalent circuit representation of memory array 190 of FIGS. 5A-6, where memory cells 150 are arranged in a grid with the rows of the memory array being defined by WL terminals 70 (70a, 70b, . . . , 70m, 70n), while the columns are defined by BL terminals 74 (74a, 74b, . . . , 74p).

Examples of read and write operations on memory cell 150 are shown in FIGS. 7B-7D, according to an embodiment of the present invention. A read operation may be performed by applying the following bias conditions: a positive voltage is applied to the BW terminal 76, zero voltage is applied to SL terminal 72, a positive voltage is applied to the selected BL terminal 74 (e.g., 74a in FIG. 7B), and a positive voltage greater than the positive voltage applied to the selected BL terminal 74 is applied to the selected WL terminal 70 (e.g., 70a in FIG. 7B), and zero voltage is applied to the SUB terminal 78. The unselected BL terminals will remain at zero voltage and the unselected WL terminals will remain at zero or negative voltage.

FIG. 7B illustrates a read operation performed on selected memory cell 150a. In one particular non-limiting embodiment, about 0.0 volts is applied to SL terminal 72, about +0.4 volts is applied to the selected BL terminal 74 (74a in this example), about +1.0 volts is applied to the selected WL terminal 70 (70a in this example), about +1.5 volts is applied to BW terminal 76, and about 0.0 volts is applied to the SUB terminal. The unselected BL terminals 74 remain at 0.0 volts and the unselected WL terminals 70 remain at 0.0 volts. However, these voltage levels may vary.

A write “1” operation may be performed by applying a positive voltage to WL terminal 70, a positive voltage to BL terminal 74, zero or positive voltage to SL terminal 72, and zero or positive voltage to BW terminal 76, and zero voltage to SUB terminal 78. The unselected BL terminals will remain at zero voltage and the unselected WL terminals will remain at zero or negative voltage.

FIG. 7C illustrates a write “1” operation performed on selected memory cell 150a. In one particular non-limiting embodiment, the following bias conditions are applied to the selected memory cell 150a: a potential of about 0.0 volts is applied to SL terminal 72, a potential of about +1.0 volts is applied to selected BL terminal 74a, a potential of about +1.0 volts is applied to selected WL terminal 70a, about +1.5 volts is applied to BW terminal 76, and about 0.0 volts is applied to SUB terminal 78; while about 0.0 volts is applied to SL terminal 72, about 0.0 volts is applied to BL terminal 74, about 0.0 volts is applied to WL terminal 70, and about +1.5 volts is applied to BW terminal 76 of the unselected memory cells. However, these voltage levels may vary.

A write “0” operation may be performed by applying a negative voltage to WL terminal 70, a negative voltage to BL terminal 74, zero or positive voltage to SL terminal 72, and zero or positive voltage to BW terminal 76, and zero voltage to SUB terminal 78. The unselected BL terminals will remain at zero voltage and the unselected WL terminals will remain at zero or negative voltage.

FIG. 7D illustrates a write “0” operation performed on selected memory cell 150a. In one particular non-limiting embodiment, the following bias conditions are applied to the selected memory cell 150a: a potential of about 0.0 volts is applied to SL terminal 72ab, a potential of about −0.3V volts is applied to BL terminal 74a, a potential of about −0.3V volts is applied to WL terminal 70a, about +1.5 volts is applied to BW terminal 76, and about 0.0 volts is applied to SUB terminal 78; while about 0.0 volts is applied to SL terminal 72, about 0.0 volts is applied to BL terminal 74, about 0.0 volts is applied to WL terminal 70, and about +1.5 volts is applied to BW terminal 76 of the unselected memory cells. However, these voltage levels may vary.

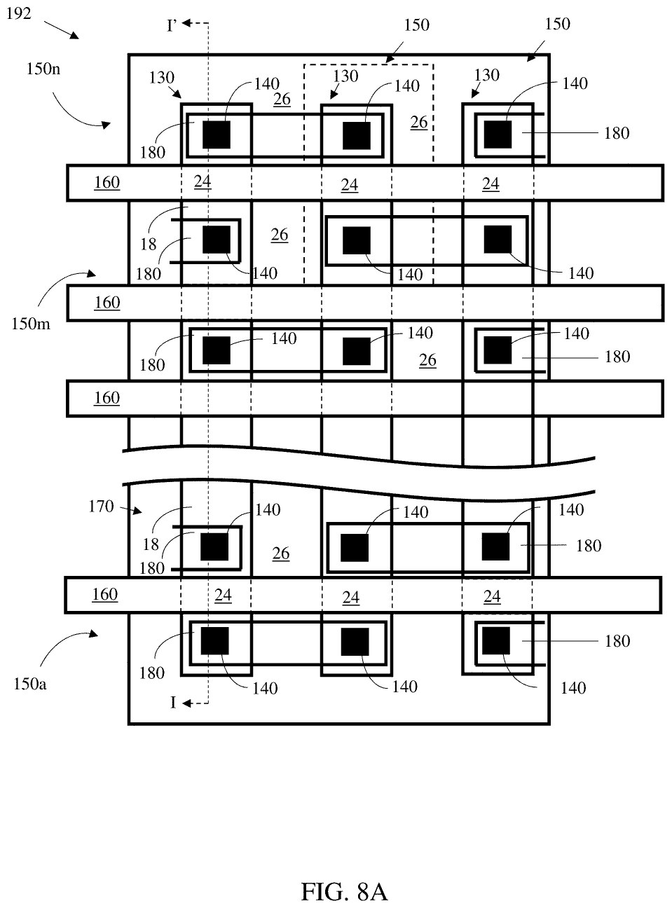

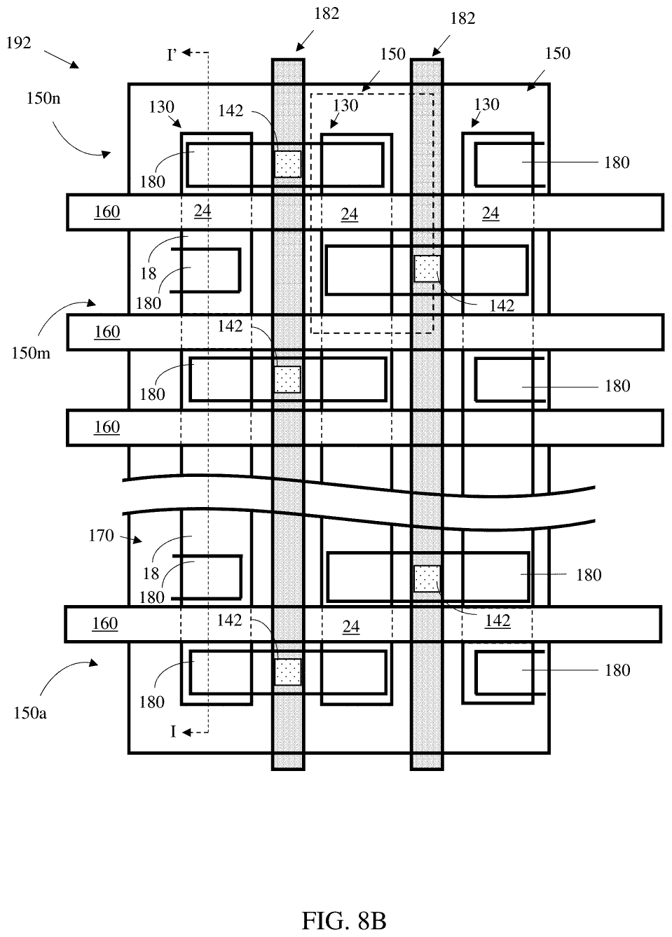

FIGS. 8A and 8B illustrate a layout view of memory array 192 according to another embodiment of the present invention. In memory array 192, MTL1 layer 180 defines connections to two adjacent CONT 140 in alternating pattern as shown in FIG. 8A. The conductive element defined by MTL1 layer can then be connected to other conductive elements, for example defined by MTL2 layer 182 through VIA1 layer 142 as shown in FIG. 8B.

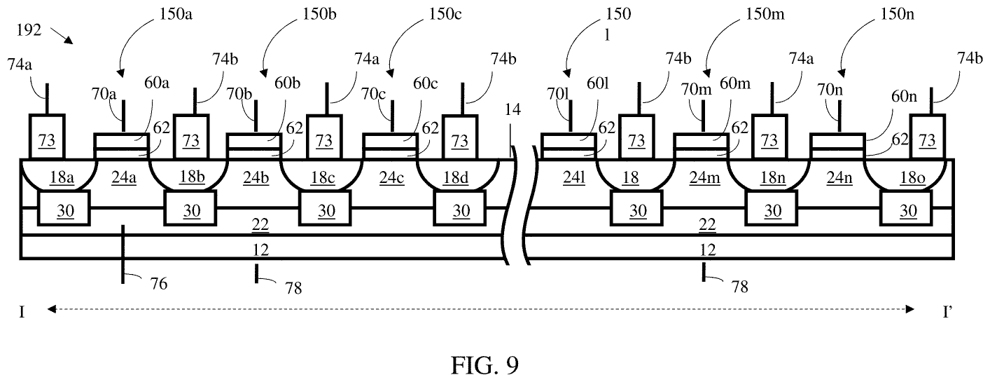

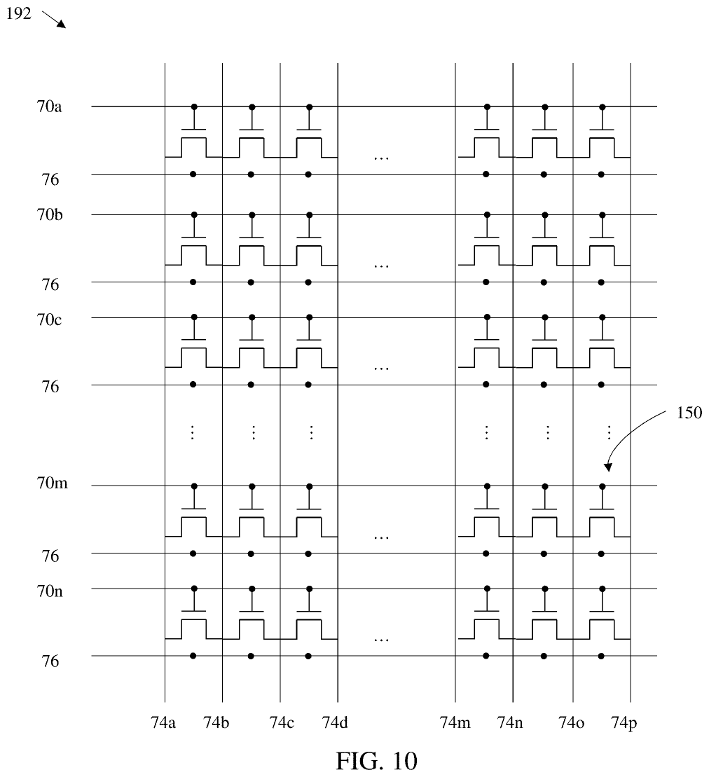

FIG. 9 illustrates a cross-sectional view of memory array 192 along the I-I′ direction shown in FIGS. 8A and 8B, while FIG. 10 illustrates an equivalent circuit representation of memory array 192 where memory cells 150 are arranged in a grid with the rows of the memory array being defined by WL terminals 70, while the columns are defined by BL terminals 74.

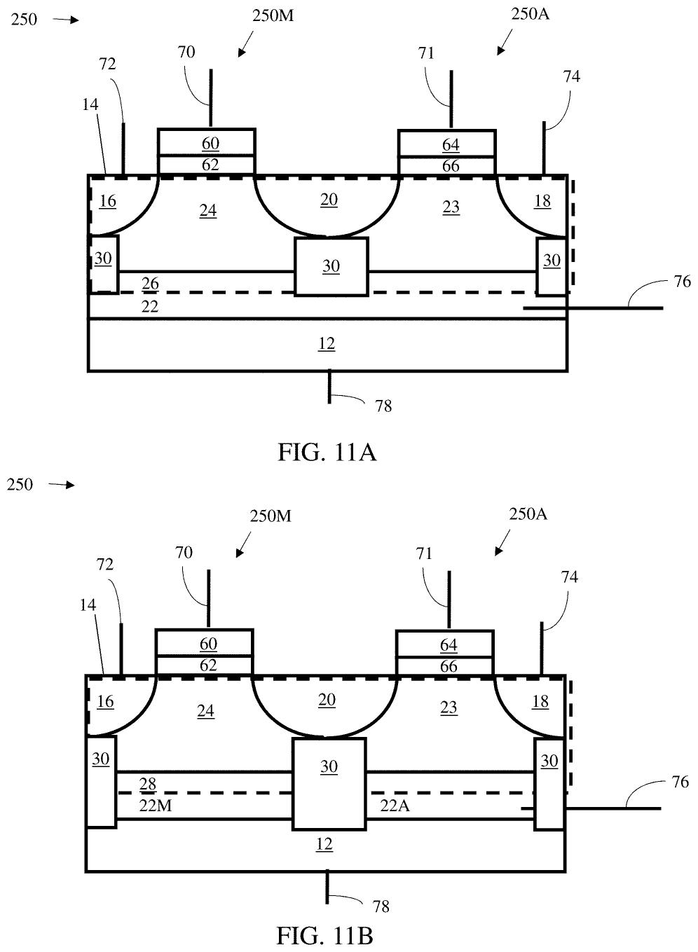

FIGS. 11A, 11B, and 12 illustrate a memory cell 250 according to another embodiment of the present invention. Memory cell 250 comprises two transistors connected in series: transistor 250M is a bi-stable floating body transistor having a floating body region 24 and an access transistor 250A. Similar to memory cells 50 and 150, floating body region 24 stores the state of the memory cell 250. Floating body region 24 is bounded on top by source line region 16, middle region 20, and insulating layer 62 (or by surface 14 in general), on the bottom by buried layer 22, on the sides by insulating layers 26 and buried insulating regions 30. A memory cell having at least two stable states comprising of a floating body transistor and an access transistor has been described, for example in U.S. Pat. No. 9,905,564, “Memory Cell Comprising First and Second Transistors and Methods of Operating” and U.S. Pat. No. 10,079,301, “Memory Device Comprising an Electrically Floating Body Transistor and Methods of Using”, which are hereby incorporated herein, in their entireties, by reference thereto.

FIG. 11A shows memory cell 250 where the bottom of buried insulating layer 30 and the bottom of insulating layer 26 are aligned inside the buried layer 22. Both the bottom of buried insulating layer 30 and the bottom of insulating layer 26 may reside inside the buried region 22 allowing buried region 22 to be continuous as shown in FIG. 11A.

Alternatively, the bottom of buried insulating layer 30 and the bottom of insulating layer 26 may not be aligned as shown in FIG. 11B. For example, the bottom of buried insulating layer 30 may reside below the buried region 22 as in FIG. 11B. This requires a shallower insulating layer 28, which insulates the floating body region 24, but allows the buried layer 22 to be continuous in one direction, for example the perpendicular direction of the cross-sectional view shown in FIG. 11B. This also allows the buried layer 22 to be separated: buried layer 22M within a memory transistor 250M and a buried layer 22A within an access transistor 250A. Different voltages may be applied to the buried layer 22M and the buried layer 22A. For example, a positive voltage to operate a bi-stable memory transistor may be applied to the buried layer 22M, while 0V or other voltage different from the voltage applied to 22M may be applied to the buried layer 22A in order to not store excess charges in the body region 23 of the access transistor 250A.

The floating body transistor 250M and the access transistor 250A may have the same conductivity type, for example, both transistors may be n-type transistors. In another embodiment, the floating body transistor 250M and the access transistor 250A may have different conductivity types, for example the floating body transistor 250M may be an n-type transistor and the access transistor 250A may be a p-type transistor.

Memory cell 250 includes word line (WL) terminal 70 electrically connected to gate 60 of the floating body transistor 250M, select gate (SG) terminal 71 electrically connected to gate 64 of the access transistor 250A, a source line (SL) terminal 72 electrically connected to source line region 16, a bit line (BL) terminal 74 electrically connected to bit line region 18, buried well (BW) terminal 76 electrically connected to the buried layer 22, and substrate (SUB) terminal 78 electrically connected to the substrate region 12.

The body region 23 of the access transistor 250A may be bounded on both sides by buried insulating regions 30 as illustrated in FIGS. 11A-11B, or may only be bounded by buried insulating region 30 on one side as shown in FIG. 12. The access transistor 250A in FIG. 12 may be mirrored, which results in the body regions 23 being common for two adjacent access transistors 250A. The common body region 23 for two adjacent access transistors 250A may then be bounded on both sides by buried insulating regions 30.

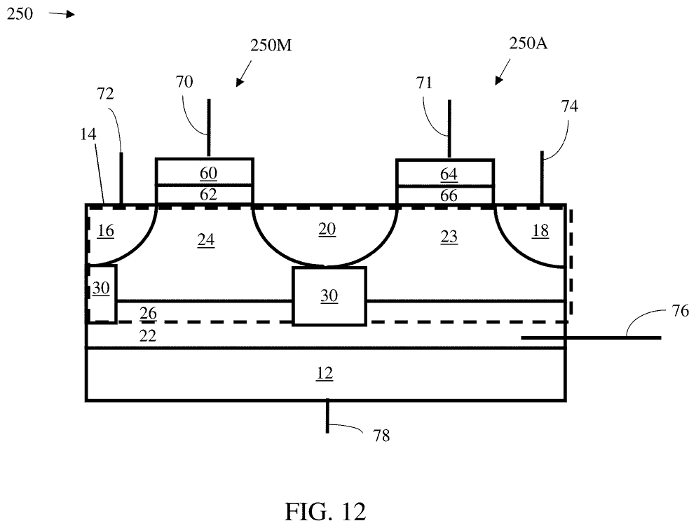

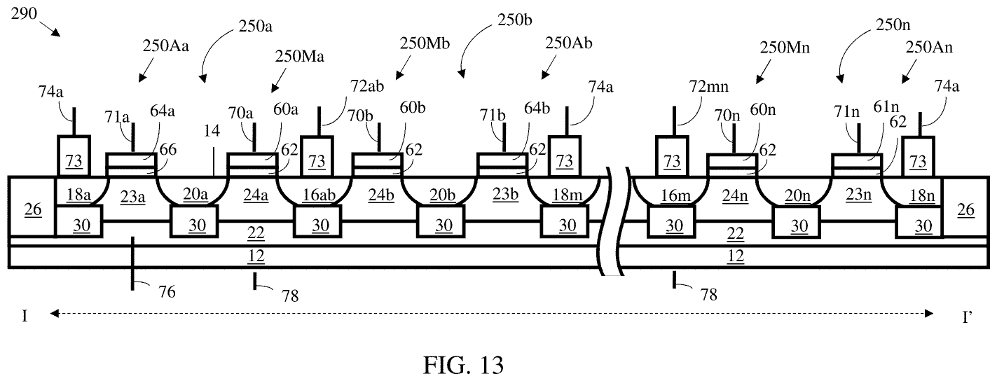

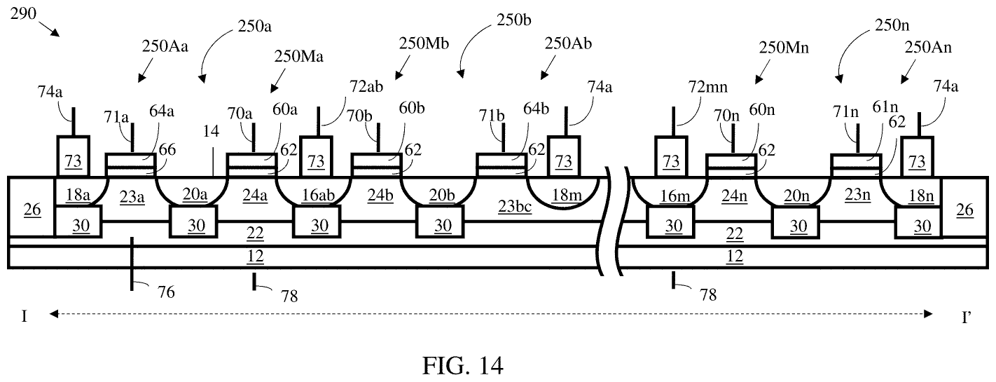

FIGS. 13 and 14 illustrate cross-sectional views of memory array 290 according to two different variants, showing a plurality of “n” memory cells 250, where “n” is a positive integer, which may range between 8 and 128. However, this embodiment and variants are not limited to the stated range, as fewer than eight or more than one hundred and twenty eight may be formed. FIG. 13 illustrates array 290 with memory cells 250, where the body regions 23 of each access transistor 250A are bounded by insulating regions 30 on both sides, whereas FIG. 14 illustrates array 290 with memory cells 250 where the body regions 23 of two access transistors 250A are bounded by insulating region 30s. For example, in FIG. 14, the body region 23bc is common between access transistors 250Ab and 250Ac (access transistor 250Ac is not shown in FIG. 14), and body region 23bc is bounded by insulating regions 30.

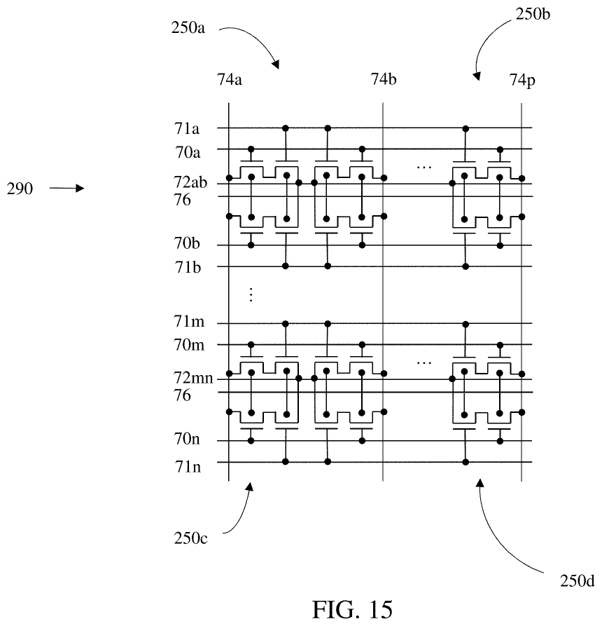

FIG. 15 illustrates an exemplary configuration of memory array 290 according to an embodiment of the present invention, where memory cells 250 are arranged in a grid with the rows of the memory array being defined by WL terminals 70, SG terminals 71, and SL terminals 72, while the columns are defined by BL terminals 74.

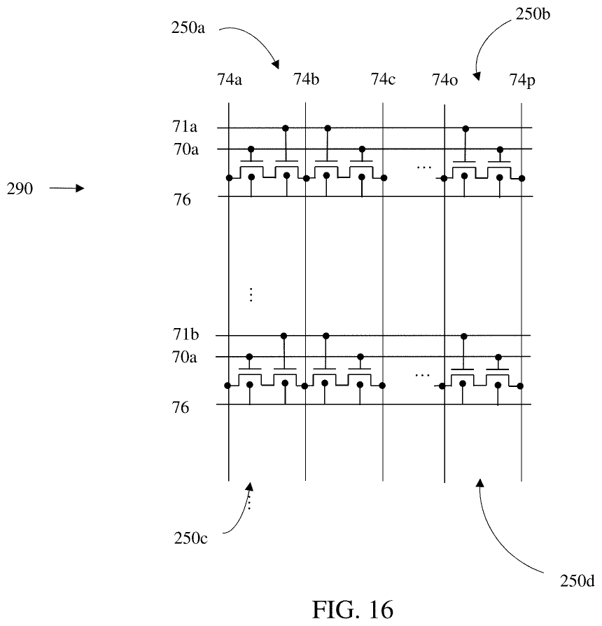

FIG. 16 illustrates an exemplary configuration of memory array 290 according to another embodiment of the present invention, where memory cells 250 are arranged in a grid with the rows of the memory array being defined by WL terminals 70, SG terminals 71, while the columns are defined by BL terminals 74.

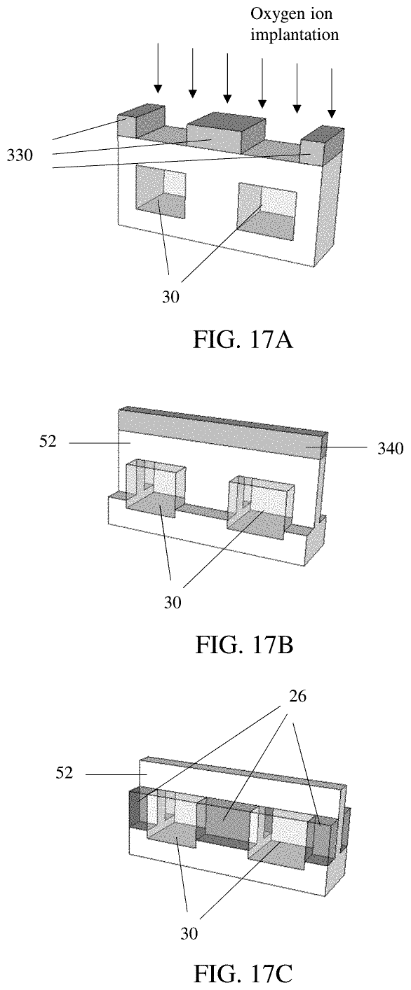

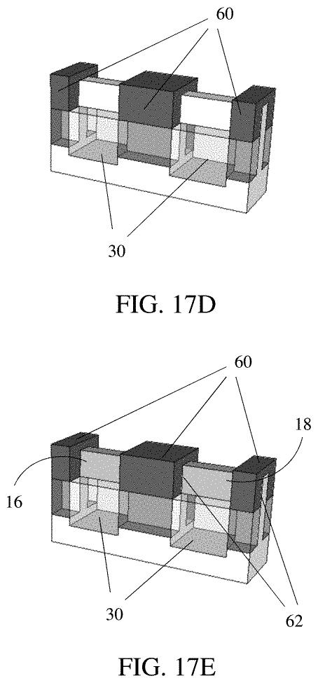

Memory cells 150, and 250 may be fabricated in a planar semiconductor substrate or may comprise a fin structure. FIGS. 17-20 illustrate exemplary fabrication steps to form memory cells 150, and 250 having buried insulating layer 30.

FIGS. 17A-17E illustrate a method to form memory cells 150, and 250 according to an embodiment of the present invention. As shown in FIG. 17A, a mask 330 is used to block regions where buried insulating layers 30 are not formed. An oxygen ion implantation and thermal annealing are then performed to form the buried insulating layers 30, followed by removal of mask 330.

Subsequently, exemplary fin formation steps are describe with references to FIG. 17B, where a mask 340 is used to define the fin region, followed by etching of the substrate region, leaving the fin region 52, followed by removal of mask 340.

The buried layer 22 may be formed before or after the fin formation steps described in regard to FIG. 17B. For simplicity, the buried layer 22 is not shown in FIGS. 17A-17E.

FIG. 17C shows the formation of insulating layer 26 through silicon oxide deposition, followed by planarization and etch back. This is subsequently followed by gate dielectric 62 and gate 60 formation steps (FIG. 17D) and source and drain regions 16 and 18 formation (FIG. 17E).

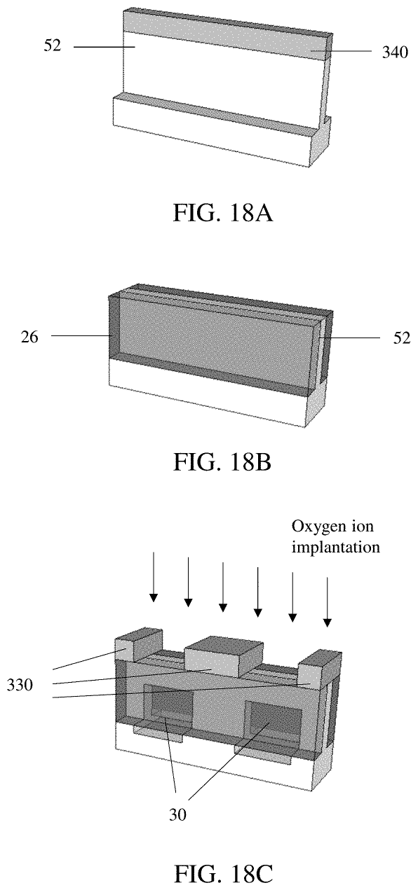

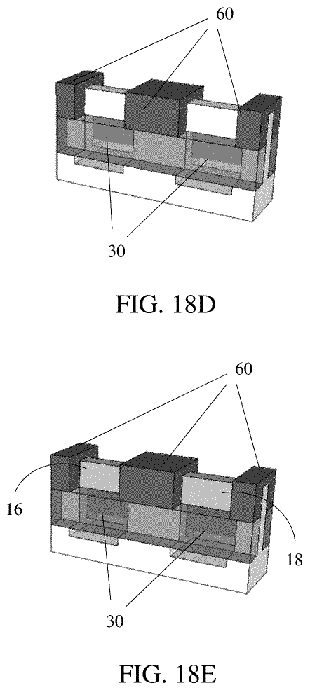

FIGS. 18A-18E illustrate a method to form buried insulating layer 30 in memory cells 150, and 250 having a fin structure according to another embodiment of the present invention. Buried layer 22 may be formed by an ion implantation process or epitaxial growth or formed through a solid state diffusion process, and for simplicity, is not shown in FIGS. 18A-18E.

FIG. 18A illustrates the fin formation step, using the mask 340 to define the fin region 52, followed by etching of the substrate region, leaving the fin region 52, followed by removal of mask 340. Subsequently, insulating layers 26 are formed as illustrated in FIG. 18B. Mask 330 is then used to block regions where buried insulating layers are not formed, as shown in FIG. 18C. An oxygen ion implantation and thermal annealing are then performed to form the buried insulating regions 30, followed by removal of mask 330.

FIG. 18D illustrates the insulating layers 26 etched back (insulating layer 26 is not shown in FIG. 18D for clarity, in order to show the buried insulating regions 30), followed by gate dielectric 62 and gate 60 formation steps, followed by source and drain regions 16 and 18 formations as shown in FIG. 18E.

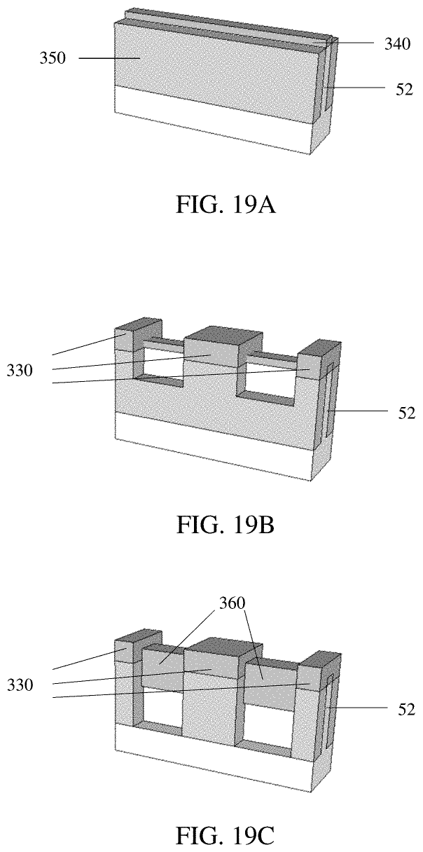

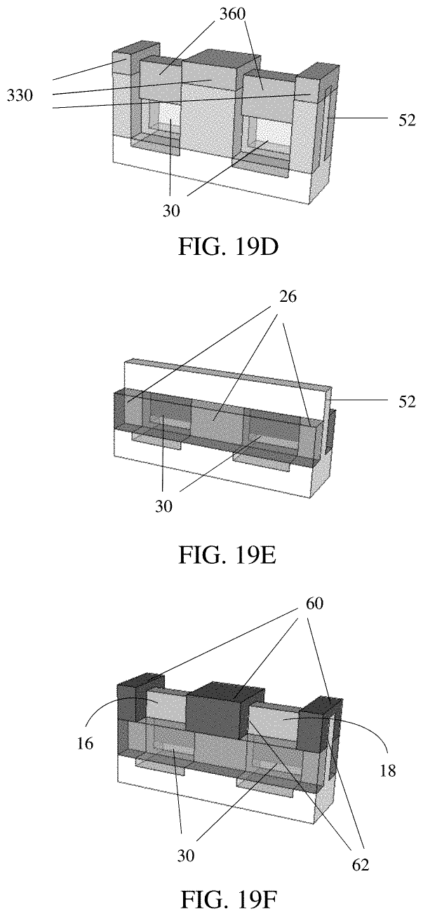

FIGS. 19A-19F illustrate a method to form buried insulating layer 30 in memory cells 150, and 250 having a fin structure according to another embodiment of the present invention. Buried layer 22 may be formed by an ion implantation process or epitaxial growth or formed through a solid state diffusion process, and for simplicity, is not shown in FIGS. 19A-19F.

FIG. 19A illustrates the fin formation step, using the mask 340 to define the fin region 52. A sacrificial layer 350 is then used to fill the regions between adjacent fins 52. Mask 330 is then used to block regions where buried insulating layers are not formed, as shown in FIG. 19B. FIG. 19C illustrates spacer mask formation 360 to protect the fin 52, followed by etching of the remaining sacrificial layer 350 to expose the bottom portion of fin 52.

Subsequently, thermal oxidation and annealing are performed until the bottom portion of the fin is consumed into buried insulating layer 30, as shown in FIG. 19D. FIG. 19E shows the subsequent steps of mask and sacrificial layer removals, and formation of insulating layer 26. FIG. 19F illustrates the formation of gate oxide 62, gate 60, and source and drain regions 16 and 18.

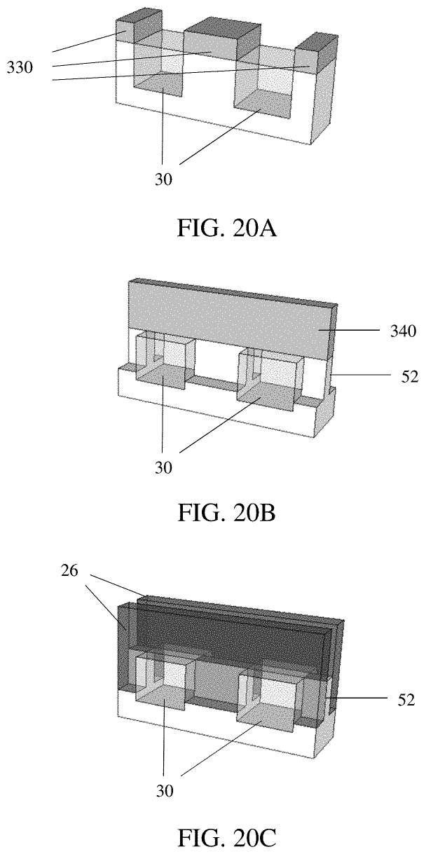

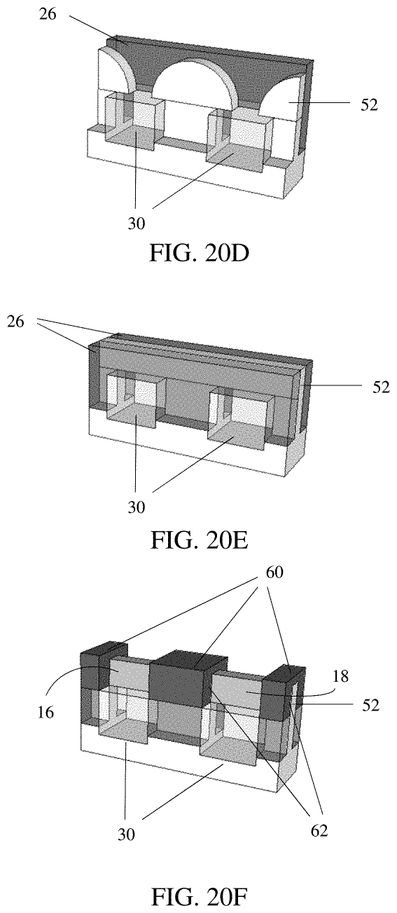

FIGS. 20A-20F illustrate a method to form buried insulating layer 30 in memory cells 150, and 250 having a fin structure according to another embodiment of the present invention. Buried layer 22 may be formed by an ion implantation process or epitaxial growth or formed through a solid state diffusion process, and for simplicity, is not shown in FIGS. 20A-20F.

As shown in FIG. 20A, a mask 330 is used to block regions where buried insulating layers 30 are not formed. The silicon substrate is then etched, followed by silicon oxide fill to form buried insulating layers 30 and removal of mask 330.

FIG. 20B shows the fin formation steps using mask 340, where the silicon substrate is etched. Subsequently, the regions on both sides of the fin (i.e., regions between adjacent fins) are filled with silicon oxide, followed by the mask 340 removal as shown in FIG. 20C. A confined epitaxial lateral overgrowth of silicon is then performed to grow the fin region 52, as shown in FIG. 20D (the front layer of the silicon oxide 26 is removed for drawing clarity). Following the confined epitaxial lateral overgrowth, a planarization step is performed as illustrated in FIG. 20E. This is then followed by insulating layer 26 etch back and the formation of gate oxide 62, gate 60, source and drain region 16 and 18 as shown in FIG. 20F.

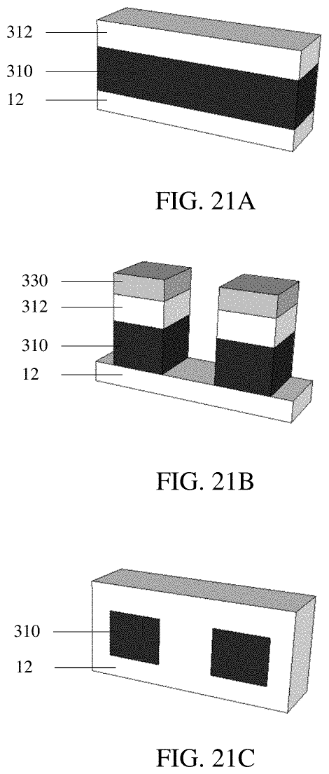

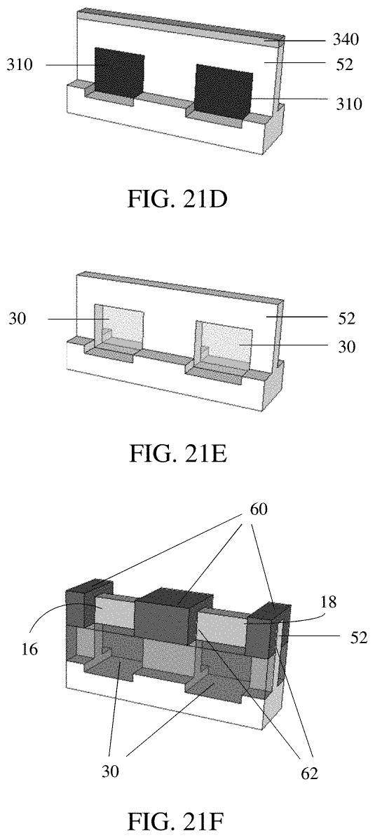

FIGS. 21A-21F illustrate a method to form buried insulating layer 30 in memory cells 150, and 250 having a fin structure according to another embodiment of the present invention. Buried layer 22 may be formed by an ion implantation process or epitaxial growth or formed through a solid state diffusion process, and for simplicity, is not shown in FIGS. 21A-21F.

SiGe and Si epitaxial growth are used to grow SiGe region 310 and Si region 312, respectively, as shown in FIG. 21A. Mask 330 is then used to pattern and etch the areas where the buried insulating layers 30 are to be formed, as shown in FIG. 21B. Following the mask 330 removal, silicon epitaxy and planarization are performed, as shown in FIG. 21C.

FIG. 21D illustrates the fin 52 formation steps using mask 340. Following the mask 340 removal, the SiGe 310 is subsequently etched. The gap region left by SiGe is then filled with silicon oxide to form insulating layer 30, as illustrated in FIG. 21E. This is then followed by insulating layer 26 formation (insulating layer 26 is not shown in FIG. 21E for clarity to show the buried insulating layer 30) and etch back and the formation of gate oxide 62, gate 60, source and drain region 16 and 18 as shown in FIG. 21F.

From the foregoing it can be seen that a memory cell having an electrically floating body has been described. While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope of the invention as claimed.

While the present invention has been described with reference to the specific embodiments thereof, it should be understood by those skilled in the art that various changes may be made and equivalents may be substituted without departing from the true scope of the invention. In addition, many modifications may be made to adapt a particular situation, material, composition of matter, process, process step or steps, to the objective and scope of the present invention. All such modifications are intended to be within the scope of the claims appended hereto.

1. A semiconductor memory cell comprising:
a floating body region configured to be charged to a level indicative of a state of the memory cell;
a first region in electrical contact with said floating body region;
a second region in electrical contact with said floating body region and spaced apart from said first region;
a gate positioned between said first and second regions;
a buried layer beneath said floating body region;
an insulating layer configured to insulate the memory cell from adjacent memory cells in a first direction; and
a buried insulating layer configured to insulate the memory cell from adjacent memory cells in a second direction perpendicular to said first direction.

2. The semiconductor memory cell of claim 1, wherein said buried insulating layer does not extend to a surface of the memory cell, but is buried beneath the first and second regions.

3. The semiconductor memory cell of claim 1, wherein said buried layer is configured to inject charge into or extract charge out of said floating body region to maintain said state of the memory cell.

4. The semiconductor memory cell of claim 1, wherein said first region has a first conductivity type selected from a p-type conductivity type and an n-type conductivity type;
said floating body region has a second conductivity type selected from said p-type and n-type conductivity types, said second conductivity type being different from said first conductivity type;
said second region has said first conductivity type; and
said buried layer has said first conductivity type.

5. The semiconductor memory cell of claim 1, further comprising a substrate beneath said buried layer, said substrate having a first conductivity type selected from a p-type conductivity type and an n-type conductivity type;
wherein said first region has a second conductivity type selected from said p-type and n-type conductivity types, said second conductivity type being different from said first conductivity type;
wherein said floating body region has said first conductivity type;
wherein said second region has said second conductivity type; and
wherein said buried layer has said second conductivity type and is positioned between said floating body region and said substrate.

6. The semiconductor memory cell of claim 1, wherein
a bottom of said buried insulating layer ends inside said buried layer; and
a bottom of said insulating layer ends inside said buried layer.

7. The semiconductor memory cell of claim 1, wherein:
a bottom of said buried insulating layer extends below a bottom of said buried layer; and
a bottom of said insulating layer ends inside said buried layer.

8. A semiconductor memory array comprising a plurality of the semiconductor memory cells of claim 1 arranged in a matrix of rows and columns.

9. A semiconductor memory cell comprising:
a bi-stable floating body transistor and an access transistor connected in series;
said bistable floating body transistor comprising a first floating body region and a first region in electrical contact with said first floating body region;
said access transistor comprising a second body region and a second region in contact with said second body region;
a third region in contact with said first floating body region and said second body region;
a gate positioned between said first region and said third region;
a buried layer beneath said first floating body region;
an insulating layer configured to insulate the memory cell from adjacent memory cells in a first direction; and
a buried insulating layer configured to insulate said first floating body region from an adjacent memory cell in a second direction perpendicular to said first direction, and to insulate said first floating body region from said second body region.

10. The semiconductor memory cell of claim 9, where said buried insulating layer is additionally provided beneath said second region to insulate said second body region on a side opposite of a side where said buried insulating layer insulates said second body region from said first floating body region.

11. The semiconductor memory cell of claim 9, wherein said buried layer is also provided beneath said second body region.

12. The semiconductor memory cell of claim 9, wherein said buried insulating layer does not extend to a surface of the memory cell.

13. The semiconductor memory cell of claim 9, wherein said buried layer is configured to inject charge into or extract charge out of said first floating body region to maintain said state of the memory cell.

14. The semiconductor memory cell of claim 9, further comprising a substrate beneath said buried layer.

15. The semiconductor memory cell of claim 9, wherein
a bottom of said buried insulating layer ends inside said buried layer; and
a bottom of said insulating layer ends inside said buried layer.

16. The semiconductor memory cell of claim 9, wherein:
a bottom of said buried insulating layer extends below a bottom of said buried layer; and
a bottom of said insulating layer ends inside said buried layer.

17. A semiconductor memory array comprising a plurality of the semiconductor memory cells of claim 9 arranged in a matrix of rows and columns,

18. A method of making a semiconductor memory cell, said method comprising:
performing oxygen ion implantation and thermal annealing to form buried insulating layers;
forming a fin;
forming a buried layer region;
forming an insulating layer by silicon oxide deposition, followed by planarization and etch back; and
forming gate dielectric, gate, and source and drain regions.

19. A method of making a semiconductor memory cell, said method comprising:
forming a buried layer in a substrate by ion implantation, epitaxial growth or through a solid state diffusion process;
forming a fin;
forming insulating layers;
performing oxygen ion implantation and thermal annealing to form the buried insulating layers;
forming gate dielectric and a gate; and
forming source and drain regions.

20. A method of making semiconductor memory cells, said method comprising:
forming a buried layer in a substrate by an ion implantation process or epitaxial growth or through a solid state diffusion process;
forming a fin region by masking a region of the substrate and etching regions adjacent to the region that was masked;
filling regions between adjacent fin regions with a sacrificial layer;
masking regions where buried insulating layers are not to be formed;
forming a spacer mask to protect the fin;
etching of the sacrificial layer to expose a bottom portion of the fin; and
performing thermal oxidation and annealing until the bottom portion of the fin is consumed into the buried insulating layer.

21. A method of making semiconductor memory cells, said method comprising:
masking regions of a substrate where buried insulating layers are not to be formed;
etching the substrate;
filling voids formed by said etching with silicon oxide fill to form the buried insulating layers; and
removing the masking.

22. The method of claim 21, further comprising:
masking a portion of the substrate where a fin is to be formed;
etching the substrate at unmasked locations adjacent the masked portion;
filling in the etched out regions on both sides of the fin with silicon oxide;
removing the masking; and
epitaxially, laterally overgrowing silicon to grow the fin.

23. A method of making a buried insulator layer in a semiconductor memory cell, said method comprising:
epitaxially growing SiGe and Si regions respectively on a substrate;
etching the SiGe and Si regions where the buried insulator layer is to be formed;
epitaxially growing silicon;
planarizing the epitaxially grown silicon;
forming a fin;
etching the SiGe regions; and
forming the buried insulator layer.
